(19) United States
(12) Patent Application Publication
(10) Pub. No.: US 2009/0080276 A1
(43) Pub. Date: Mar. 26, 2009

(54) Temperature Dependent Bias for Minimal Stand-by Power in CMOS Circuits

(76) Inventors: Jin Cai, Cortlandt Manor, NY (US); Randy William Mann, Burlington, NC (US); Harold Pilo, Underhill, VT (US)

Correspondence Address: INNOVATION INTERFACE, LLC, 303 TABER AVENUE, PROVIDENCE, RI, 02906, US

(21) Appl. No.: 11/859,775

(22) Filed: Sep. 23, 2007

(51) Int. Cl. G05F 1/567; G11C 7/04; H03K 17/16

(52) U.S. Cl. 365/212; 326/32; 327/541

(57) ABSTRACT

A circuit is disclosed which generates such a bias voltage that when this bias voltage is received by a large plurality of devices of a semiconductor chip, power consumption is reduced in the stand-by mode at any particular operating temperature. The disclosed circuit contains at least one monitor FET, which is kept in its off-state, and which has common properties with the large plurality of FET devices. The temperature dependent leakage current of the monitor FET is sensed, and used to generate the bias voltage in proportion to the leakage current. This bias voltage is received by the large plurality FET devices on their gate electrodes, or on their body terminals.

### FIELD OF THE INVENTION

The present invention is related to semiconductor integrated circuits, and more particularly to a system and method for minimizing power consumption in the stand-by mode at all operating temperatures.

### BACKGROUND OF THE INVENTION

Today's integrated circuits include a vast number of devices. As FET (Field-Effect-Transistor) devices are being scaled down, the technology becomes more complex, and device behavior deviates from the ideal textbook case. One problem is leakage current in off-state FET devices. Although such leakage current my be small, with the large number of devices, in excess of 10⁷ in some semiconductor circuits, and with the leakage current continuously flowing, the power consumption due to leakage current in the stand-by mode of the circuits is a significant problem. As devices are becoming ever smaller, the stand-by mode power consumption problem is expected to increase. There are fabrication and device design techniques which aim to decrease the off-state leakage current. However, the off-state leakage current is temperature dependent. And, while, a given device design may be effective in optimally minimizing leakage current at one given temperature, for instance at room temperature, there is no general system or method known, which could optimally minimize the off-state leakage current at any given temperature within the whole operating temperature range.

### SUMMARY OF THE INVENTION

In view of the discussed difficulties, embodiments of the present invention disclose a semiconductor circuit having voltage rails, a low rail, and a high rail. The semiconductor circuit further contains at least one monitor FET having a gate electrode, which gate electrode is tied to a first voltage. The first voltage keeps the monitor FET in the off-state. In the off-state, the monitor FET has a temperature dependent leakage current. The semiconductor circuit further has a sensing circuit which contains the monitor FET. The sensing circuit produces a first output voltage, which first output voltage is responsive to the temperature dependent leakage current. The semiconductor circuit further contains a feedback circuit, which receives the first output voltage and is capable to generate a second output voltage, which second output voltage is in proportion with the temperature dependent leakage current. The voltage value of the second output voltage is typically outside of the voltage rails. The semiconductor circuit further has a large plurality of FET devices having common properties with the at least one monitor FET, including the temperature dependent leakage current. The large plurality of FET devices are receiving the second output voltage, and the second output voltage is reducing the temperature dependent leakage current in the large plurality of FET devices.

Embodiments of the present invention further disclose a method for reducing a temperature dependent leakage current in a semiconductor circuit. The method includes the sensing of the temperature dependent leakage current of at least one monitor FET. The method further includes the generation of a bias voltage in proportion to the sensed temperature dependent leakage current. In the method the bias voltage is received in a large plurality of FET devices of the semiconductor circuit, where the large plurality of FET devices have common properties with the monitor FET. In this manner the bias voltage is suitable to decrease the temperature dependent leakage current in the large plurality of FET devices.

### BRIEF DESCRIPTION OF THE DRAWINGS

These and other features of the present invention will become apparent from the accompanying detailed description and drawings, wherein:

FIG. 1 shows sub-threshold leakage (I_{d}), and drain/body junction leakage current (I_{b}), as functions of gate voltage at three temperatures;

FIG. 2A shows sub-threshold leakage (I_{d}), and drain/body junction leakage current (I_{b}), as functions of body voltage at 25° C.;

FIG. 2B shows sub-threshold leakage (I_{d}), and drain/body junction leakage current (I_{b}), as functions of body voltage at 120° C.;

FIG. 3 shows an exemplary embodiment of a voltage regulating circuit generating temperature dependent bias voltage;

FIG. 4A shows an alternate embodiment for the sensing circuit portion of the voltage regulating circuit;

FIG. 4B shows a further alternate embodiment for the sensing circuit portion of the voltage regulating circuit;

FIG. 5 shows an exemplary embodiment of a wordline driver utilizing the temperature dependent bias voltage;

FIG. 6A shows an exemplary embodiment of a SRAM memory cell where negative bias voltage may be is applied to the gate electrodes of the pass transistors;

FIG. 6B shows an exemplary embodiment of a SRAM memory cell where appropriate polarity bias voltage may be is applied to the body terminals of transistors;

FIG. 7A shows an exemplary embodiment of a DRAM memory cell where negative bias voltage may be is applied to the gate electrode of the transfer transistor; and

FIG. 7B shows an exemplary embodiment of a DRAM memory cell where negative bias voltage may be is applied to the body terminal of the transfer transistor.

### DETAILED DESCRIPTION OF THE INVENTION

It is understood that Field Effect Transistor (FET) devices are well known in the electronic arts. Standard contacts to the FET, include the source electrode, the drain electrode, the gate electrode, and the body terminal. Terminal and electrode are equivalent terms used in the art. There are two type of FET devices: a hole conduction type, called PFET, and an electron conduction type, called NFET. Often, but not exclusively, PFET and NFET devices on the same chip are wired into CMOS circuits. A CMOS circuit contains at least one PFET device and at least one NFET device.

In FET operation an inherent electrical attribute is the threshold voltage. When the voltage between the source and the gate exceeds the threshold voltage, in the so called on-state, the FETs are capable to carry current between the source and the drain. When the voltage between the source and the gate is less than the threshold voltage, in the so called off-state, the FETs are not carrying current between the source and the drain. Since the threshold is a voltage difference between the gate and the source of the device, in general, NFET threshold voltages are positive values, and PFET threshold voltages are negative values.

In FET semiconductor circuits one usually finds voltage rails, well known in the art. Typically, the voltage rails are the circuit's power supply voltage values, which in state of the art circuits are at, or below, about 1.5V. Thus, for instance, a circuit with a 1.2V power supply may have a low rail of 0V, and a high rail of 1.2V. Ideally, internal nodes of CMOS circuits have voltage swings between the two rail values. Also, in standby mode, namely when not switching, the internal nodes are at voltage values equaling either the high, or the low rail. There are exception to such generalizations, well known in the art, for instance in cases of pass transistors or transfer transistors, but it is generally true that any voltage swing, or voltage on a node, is bounded by the low rail voltage and the high rail voltage. If in a semiconductor circuit one desires to use a voltage value outside the bounds of the voltage rails, generally such a voltage value may have to be purposefully generated by some means. Such means are know in the art.

One of the advantages of ideal CMOS circuits is that they consume power only during their switching, in the so called active mode. However, with scaling to ever smaller device dimensions, leakage current, and power consumption due to leakage current, in the non-switching state, in the so called stand-by mode, becomes a detrimental issue that one may have to deal with.

An ideal FET device conducts in its on-state, namely when the gate voltage is above threshold, and carries no significant current in its off-state, namely when the gate voltage is below threshold. Typically, the bias conditions of the off-state of a FET in a CMOS circuit are such that the gate-to-source voltage, Vgs, is 0V, and the drain-to-source voltage, Vds, is the full rail voltage, marked usually as Vdd. In FET devices, for a variety of reasons known in the art, there may be non-negligible current flowing even in the off-state. This off-state current is generally referred to as the leakage current.

The FET off-state leakage current, in general, is temperature dependent. Since operating chip temperatures can vary greatly from about −20° C. to over 100° C., depending on environment, chip power level, heat conduction, and other conditions, the power dissipation in the stand-by mode due to leakage may vary depending on temperature. Appropriate transistor design may minimize leakage current for a particular operating temperature, but one would prefer to minimize the leakage current at any temperature, and keep it at the minimum pertaining to the given temperature, as the temperature changes.

It is known in the art that there may be two major components of leakage current: sub-threshold leakage (I_{d}), and drain/body junction leakage current, (I_{b}). Increasing channel doping concentration may reduce I_{d} but also may increase I_{b}, possibly due to a field-dependent band-to-band tunneling mechanism. For low leakage applications, channel doping concentration is usually optimized, such that the two components are more or less equal to each other. This results in minimum leakage current in the FET off-state at one particular temperature, e.g., at 25° C.

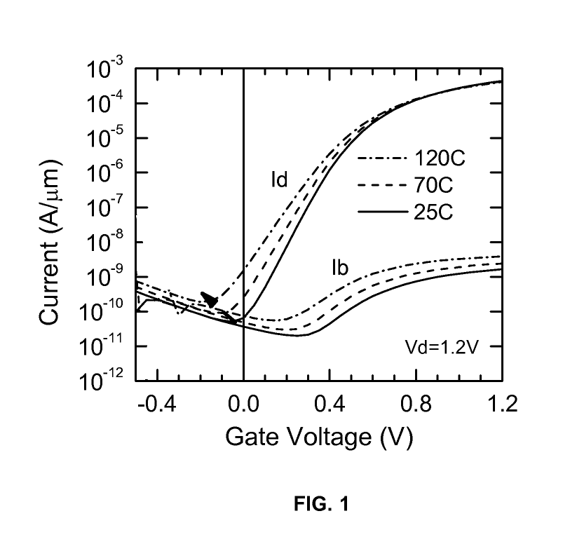

FIG. 1 shows sub-threshold leakage (I_{d}), and drain/body junction leakage current (I_{b}), as functions of gate voltage at three temperatures for an NFET. As the gate of the NFET is biased more negatively, the I_{d} reduces as the transistor is turned off more strongly, while I_{b} increases due to a known effect, the so called gate-induced-drain-leakage (GIDL) effect. The different gate voltage dependence of the two currents contributing to the off-state leakage results in a differing optimum gate bias for minimum total leakage current at each temperature. For the NFET shown in FIG. 1, for which the design is such to optimize minimum leakage at room temperature (25° C.), at 120° C. the optimum gate bias would be about −200 mV. At this temperature the leakage current reduction from Vgs=0V to Vgs=−200 mV is about a factor of 8. Looking at 70° C., the optimum gate bias would be about −100 mV for a leakage current reduction factor of about 2.7, compared to the 25° C. optimum Vgs=0V. The thick arrow indicates the movement of the leakage current minimum as temperature changes.

Alternatively, one may influence the off-state leakage current by supplying a voltage bias to the body terminal of an FET. For NFETs, a negative body bias reduces the sub-threshold leakage current, I_{d}, due to an increased threshold voltage, but increases the p/n junction leakage current, I_{b}, due to an increased voltage drop across the drain/body p/n junction. Such device physics dictates that an optimum body bias exists for minimum total leakage current, and that the optimum body bias is also temperature dependent.

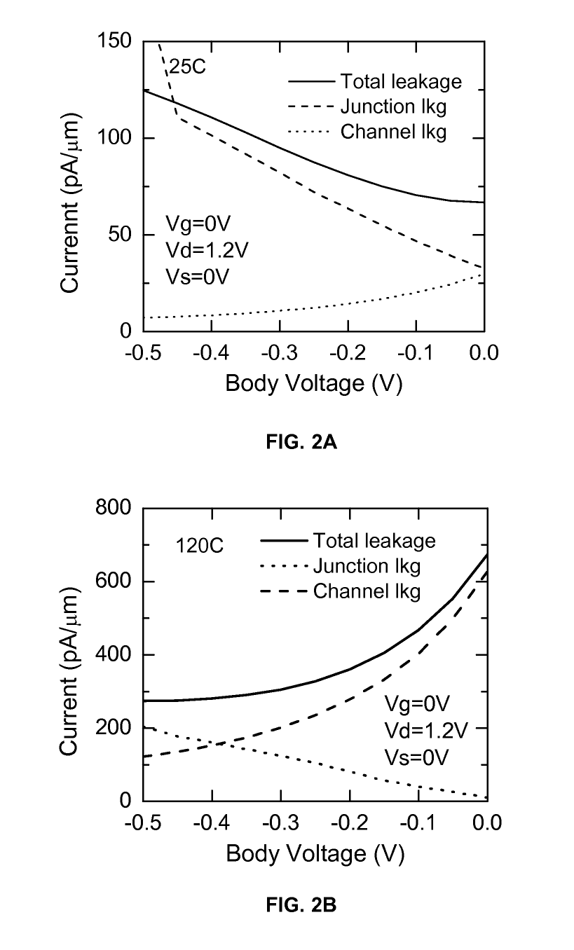

FIG. 2A shows sub-threshold leakage (I_{d}), and drain/body junction leakage current (I_{b}), as functions of body voltage at 25° C. for an NFET. For the design of this transistor the optimum body bias is close to zero volt. With increasing negative body bias, the rate of increase in I_{b} is faster than the rate of reduction in I_{d}, and as a result the overall leakage current increases with a negative body bias. This transistor does not need a reverse body bias at 25° C. Body bias is a voltage between the device body and device source. A reverse body bias for an NFET means that the body terminal is negatively biased relative to the source electrode. A reverse body bias for a PFET means that the body terminal is positively biased relative to the source electrode.

FIG. 2B shows sub-threshold leakage (I_{d}), and drain/body junction leakage current (I_{b}), as functions of body voltage at 120° C. for the same NFET of FIG. 2A. At 120° C., when I_{d} is dominant over I_{b}, a negative body bias has the effect of reducing the overall leakage. The optimum bias is about −400 mV for a leakage reduction factor of about 2.5 over the zero body bias situation.

The bias voltages, discussed and shown in FIGS. 1 and 2B, that are suitable for off-state bias current suppression are generally outside the voltage rail values of the circuits. Consequently, a scheme which aims for supplying bias voltages capable to minimize leakage currents, may have to generate voltage values outside the voltage rails.

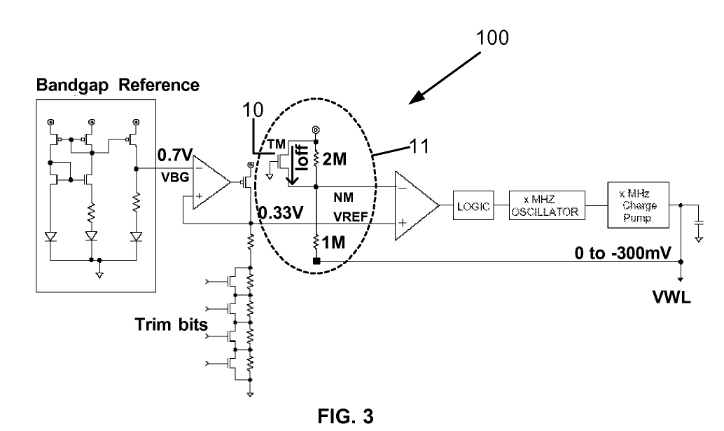

FIG. 3 shows an exemplary embodiment of a voltage regulating circuit 100 generating temperature dependent bias voltage for optimal off-state leakage current. This circuit 100 generates bias voltages below the low voltage rail and it is suitable for NFET leakage optimization. One skilled in the art would recognize, however, that with appropriate mirroring of polarities, and devices, an identical circuit can be constructed suitable for PFET leakage optimization.

FIG. 3 uses the customary symbols for indicating voltage rails, which as shown are: a low voltage rail of ground, and a high voltage rail of Vdd. The value of Vdd, as one suitable for small scaled circuits, may be between about 0.5V and 1.5V, possibly in the vicinity of about 1V. The circuit voltage regulating circuit 100 contains a monitor FET 10. This monitor FET 10 is fabricated identically with a large plurality of other FET devices, not shown in FIG. 3, that typically are present in semiconductor circuits chips. The large plurality of FET devices may be characterized as being part of a memory, such as a Dynamic Random Access Memory (DRAM), or a Static Random Access Memory (SRAM), or being components in logic circuits, such as found, for instance, in a computer processor. The monitor FET 10, thus, is expected to be a true representative of the large plurality of FET devices, as having the same leakage properties, including the temperature dependence of the leakage current.

The large plurality, regarding the FET devices, may mean a significant fraction, generally between about 2%, up to close to 100% of all FET devices in a given circuit, or on a chip. Since the art is progressing toward larger capacity circuits, in numeric terms the large plurality of FET devices may be between about 10⁴ devices all the way to about 10¹¹ devices.

The gate of the monitor FET 10 is tied to a first voltage, which keeps the monitor FET 10 in the off-state. The first voltage may typically be a voltage rail, as it is shown in FIG. 3 to be the low rail voltage, namely the ground potential. The monitor FET 10 is part of a sensing circuit 11, inside the dotted ellipse, which produces a first output voltage on node NM. This first output voltage is responsive to the temperature dependent off-state leakage current, Ioff, of the monitor FET 10. Such a sensing circuit 11 may be implemented is several ways. In a representative embodiment of the invention, implemented as a voltage divider, is shown in FIG. 3. Here, the sensing circuit 11 is a voltage divider, more particularly a resistance tree, which includes, in addition to the monitor FET 10, resistances 1M and 2M. For arriving at a convenient value for the first output voltage on node NM, the resistor 2M is about twice the size of resistor 1M. Typically, resistor 2M carries a larger current than the leakage current of the monitor FET 10. One end of the resistance tree is tied to a rail value, which is Vdd for the circuit 100 of FIG. 3.

In FIG. 3 only one monitor FET 10 is shown. It is possible that in a variant embodiment there are more than one monitor FETs, arranged in serial or in parallel manner, or in combination of these two. Having more than one FET, for instance with differing device widths, may give a better expression of typical device leakage current. However, using one FET, or more of them as monitors, in reality is not significant for the embodiments of the present invention. Any number of monitor FETs can always be treated and regarded as only one monitor FET 10 which represents all the devices.

The first output voltage on node NM is received by a feedback circuit. This feedback circuit generates a second output voltage, namely VWL, which second output voltage is in proportion to the temperature dependent leakage current of the monitor FET 10. The second output voltage, VWL, has a value outside of the voltage rails. VWL for the NFET implementation shown in FIG. 3 is a negative value, being below the low rail value, which is ground. For a PFET implementation the second output voltage would have a more positive value than the high rail, namely the node VWL would be more positive than Vdd.

The feedback circuit typically may contain: a differential amplifier, directly receiving the first output voltage of the sensing circuit 11 on node NM; a logic circuit receiving input from the differential amplifier; an oscillator; and a charge pump. The logic circuit directs the oscillator, which oscillator then controls the charge pump, and the charge pump generates a voltage outside the rail values. The oscillator and the charge pump typically operate at MHz frequencies.

The logic circuit may be programmed to take into account the particulars of the leakage current's temperature dependence, for any specific FET device embodiment. Such FET device embodiment may include, without limitation, bulk devices, SOI devices, three dimensional devices, such as FIN type devices, or any other FET arrangements known in the art; it may include devices fabricated in pure Si, in SiGe alloys, or in any other compounds; it may include devices made of single crystal, polycrystalline, amorphous, or other state and quality of material; it may include strained devices, high-k devices; and in general it may include any other known ones in the electronic arts that exhibit a temperature dependent off-state leakage current. The logic circuit also controls whether the second output voltage VWL would be used for gate bias or for body bias, since usually the body bias requires larger voltage values. Furthermore, the logic circuit programming may also take into consideration the way the second output voltage is fed back into the sensing circuit 11.

The first output voltage of the sensing circuit 11 on node NM, which is responsive to the temperature dependent leakage current in the monitor FET 10, is compared with a reference voltage, VREF, by the differential amplifier of the feedback circuit. The reference voltage VREF is essentially independent of temperature. Generating temperature independent voltages, such as VREF, have known methods in the art. Such methods typically include bandgap reference circuits. The one shown in FIG. 3 is a so called Wilson Mirror, known in the art, which generates a temperature independent voltage of a about 0.7V. This value on node VBG is then level shifted by a unity gain amplifier to a value suitable for comparison with the voltage on node NM coming from the sensing circuit. Considering the rail values of scaled semiconductor circuits, which are typically 0V ground low rail, and about 1V Vdd high rail, a 0.33V value for VREF may be a suitable value. To better adjust the VREF voltage value, in general, one may add Trim Bits to the level shifting arrangement, as shown in FIG. 3. Level shifting circuits, using unity gain amplifiers, and trim bits, are know in the art.

Since VREF is derived from a bandgap reference circuit, it is essentially independent of temperature and it may serve as a second input for the differential amplifier of the feedback circuit. As the first output voltage changes with temperature on node NM due to the change of leakage current in the monitor FET 10, a voltage difference develops between the first output voltage on node NM and VREF. This difference is then amplified and fed to the logic of the feedback circuit. The logic directs the oscillator and the charge pump to generate a second output voltage VWL in proportion to the voltage difference between the first output voltage on node NM and VREF. The second output voltage is fed back to the sensing circuit 11, for instance, as shown in FIG. 3 as the second terminal for the resistor tree, and restores the balance on the inputs of the differential amplifier between VREF and the voltage on node NM. Thus, the second output voltage VWL tracks the temperature dependent leakage current of the monitor FET 10. This tracking by the second output voltage, VWL, in proportion to the leakage current, may be the desired output of the voltage regulating circuit 100. The second output voltage VWL is then received by the large plurality of FET devices as a bias voltage, which devices have the same temperature dependent leakage current as the monitor FET 10, and their leakage current is thereby optimized. The second output voltage, VWL, typically is received by the large plurality of FET devices as a gate bias voltage, or as a body bias voltage. In this manner the stand by power consumption, due to leakage current of the semiconductor memory or logic circuits, is minimized at all operating temperatures.

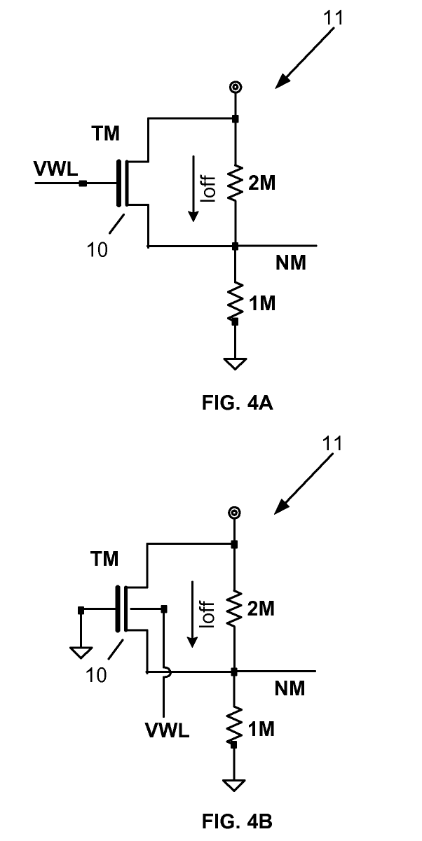

FIG. 4A shows an alternate embodiment for the sensing circuit 11 portion of the voltage regulating circuit 100. The voltage divider is implemented between the two rails, Vdd and ground. The second output voltage VWL from the feedback circuit is received on the gate of the monitor FET 10. In this embodiment the first voltage on the gate electrode of the monitor FET is actually the second output voltage. The logic in the feedback circuit assures that when VWL is of the right value for minimizing Ioff in the monitor FET, the balance is restored on the sense amplifier, which receives the first output voltage, on node NM, and receives the reference voltage, VREF.

FIG. 4B shows a further alternate embodiment for the sensing circuit 11 portion of the voltage regulating circuit 100. The voltage divider is implemented between the two rails, Vdd and ground. The first voltage on the gate of the monitor FET is again a voltage rail, as it is shown in FIG. 4B it is the low rail voltage, namely the ground potential. The second output voltage VWL from the feedback circuit is received on the body terminal of the monitor FET 10. The logic in the feedback circuit assures that when VWL is of the right value for minimizing Ioff in the monitor FET, the balance is restored on the sense amplifier, which receives the first output voltage, on node NM, and receives the reference voltage, VREF.

For the voltage regulating circuit 100 one may contemplate a further embodiment. This embodiment would also be based on sensing the off-state leakage current in a representative monitor FET 10. Again, this sensing is then used to generate a second output voltage, VWL, in proportion with this leakage current, and use VWL on the large plurality of FET devices of the memory and/or logic circuit as a bias voltage. But, instead of using a voltage divider, one may characterize the leakage current in fully digital fashion, for instance by a count. This count, for instance, may be in proportion to the discharges of a capacitor receiving the leakage current. The count would then be entered into the logic circuit, which again directs the oscillator and the charge pump to generate a second output voltage, VWL. For this embodiment, VREF and the bandgap reference circuit, and the feedback of VWL to the sensing circuit, may be omitted.

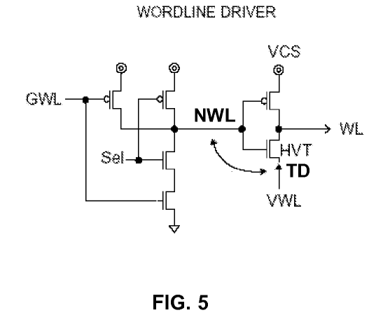

FIG. 5 shows an exemplary embodiment of a wordline driver utilizing the temperature dependent bias voltage. It is an illustration for embodiments of the invention, showing that between the voltage regulating circuit 100 and the large plurality of FET devices that receive the bias voltage, the usual standard circuits can be used, however, occasional slight modifications may be necessary. The basic structure of the circuit in FIG. 5 is that of a well known NFET wordline driver, serving NFET based memories. Those skilled in the art would recognize that the wordline connects to the gates of the devices in the memory cells. When a memory cell is not selected, namely when the voltage on the NWL node is at the high rail value of Vdd, the second output voltage VWL passes through the deselect device, TD, and reaches the gates of the cell devices through the wordline, WL. However, in order to properly select the memory cell, as know in the art by turning on appropriate voltages, such as a global wordline signal, GWL, and a select signal, Sel, the deselect device TD may have to be a non-standard device. When the cell is selected the voltage on NWL node goes to the low rail value, which may be ground, while the source of the deselect device TD is at VWL, which may be more negative than ground. If the deselect device, TD, would be a standard device, it might not fully turn off. This would be because its gate-to-source voltage is positive, namely it is the absolute value of the bias voltage, VWL. By using a high threshold, HVT, device for the deselect device, TD, with a threshold which is higher than the absolute value of VWL, one can assure that this deselect device is completely turned off during wordline WL selection.

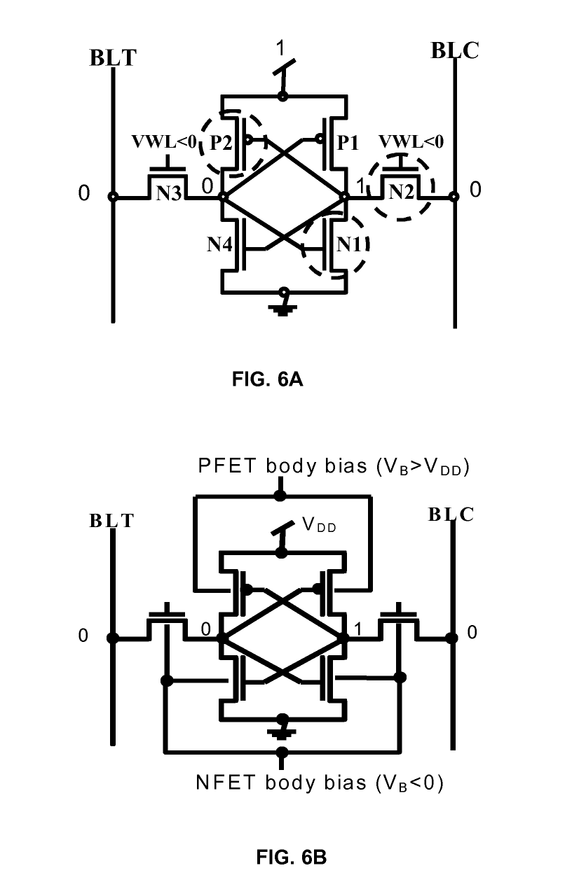

FIG. 6A shows an exemplary embodiment of a SRAM memory cell where negative bias voltage may be is applied to the gate electrodes of the pass transistors. This figure shows the circuit diagram for a well known 6-transistor SRAM cell in the stand-by mode. In the-stand by mode three of the six transistors are in the off-state and generate leakage currents. These are one of the pull down NFET (N1), one of the pull-up PFET (P2), and one pass-gate NFET (N2). The wordlines, carrying the second output voltage, VWL, are connected to the gate terminals of the pass-gate NFETs. The negative wordline bias VWL optimally reduces the leakage in the pass-gate NFET (N2), thereby lowers the overall SRAM stand by mode power consumption in an optimized fashion.

FIG. 6B shows an exemplary embodiment of a SRAM memory cell where appropriate polarity bias voltage may be is applied to the body terminals of transistors. A negative body bias coming from a voltage regulating circuit 100 suitable for NFET leakage optimization can be applied to the pass-gate NFET and pull-down NFETs in the SRAM cell. For the pass-gate NFETs, either the negative wordline bias, as shown in relation with FIG. 6A, or the negative body bias may be used. For the pull-down NFETs, the gate terminal is not accessible for biasing, and only the negative body bias is feasible. Together with negative biases, V_{B}<0, or by itself, a body bias more positive than Vdd, coming from a voltage regulating circuit suitable for PFET leakage optimization, V_{B}>Vdd can also be applied to pull-up PFETs in the SRAM cell. Thereby, with body-bias one can lower the overall SRAM stand by mode power consumption in an optimized fashion.

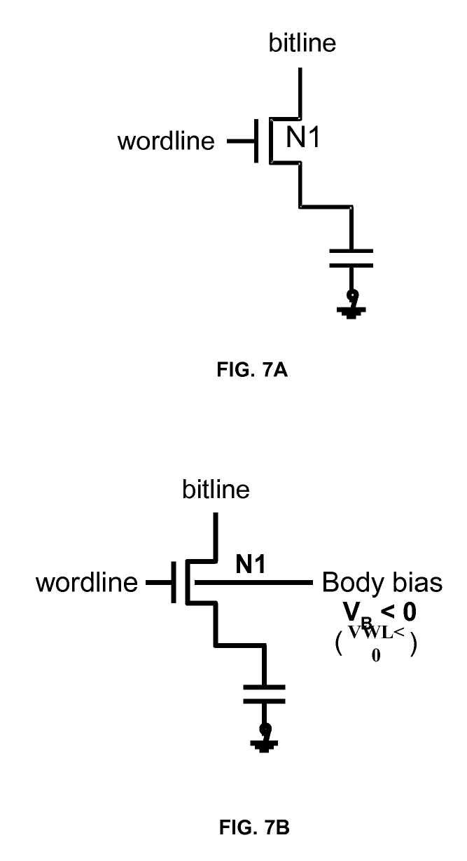

FIG. 7A shows an exemplary embodiment of a DRAM memory cell where negative bias voltage may be is applied to the gate electrode of the transfer transistor. The negative wordline technique is also applicable to DRAM cells. A leakage reduction optimized negative wordline voltage, the second output voltage VWL<0V, from the voltage regulating circuit 100, applied as a bias voltage to the gate electrode of the access NFET of the DRAM cell, can optimally minimize the leakage current in the DRAM cell. In a dynamic memory cell, leakage reduction not only reduces stand-by power, but also increases data retention time. The negative gate bias lowers the overall DRAM stand-by mode power consumption in an optimized fashion.

FIG. 7B shows an exemplary embodiment of a DRAM memory cell where negative bias voltage may be is applied to the body terminal of the transfer transistor. The negative body bias technique is also applicable to DRAM cells. A leakage reduction optimized negative body bias voltage, the second output voltage VWL<0V, from the voltage regulating circuit 100, applied as a bias voltage to the body terminal of the access NFET of the DRAM cell, can optimally minimize the leakage current in the DRAM cell. In a dynamic memory cell, leakage reduction not only reduces stand-by power, but also increases data retention time. The negative body bias lowers the overall DRAM stand-by mode power consumption in an optimized fashion.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art. The scope of the invention is defined by the appended claims.

We claim:

1. A semiconductor circuit, comprising:
voltage rails, a low rail, and a high rail;
at least one monitor FET having a gate electrode, wherein the gate electrode is receiving a first voltage, wherein the first voltage keeps the at least one monitor FET in an off-state, wherein in the off-state the at least one monitor FET has a temperature dependent leakage current;
a sensing circuit comprising the at least one monitor FET, wherein the sensing circuit produces a first output voltage, wherein the first output voltage is responsive to the temperature dependent leakage current;
a feedback circuit receiving the first output voltage and being capable to generate a second output voltage which second output voltage is in proportion to the temperature dependent leakage current, wherein the sensing circuit is receiving the second output voltage, and wherein the second output voltage has a value outside of the voltage rails; and
a large plurality of FET devices having common properties with the at least one monitor FET, including the temperature dependent leakage current, wherein the large plurality of FET devices receive the second output voltage, wherein the second output voltage reduces the temperature dependent leakage current in the large plurality of FET devices.

2. The semiconductor circuit of claim 1, wherein the sensing circuit is a voltage divider implemented between one of the voltage rails and the second output voltage, and wherein the first voltage is one of the voltage rails.

3. The semiconductor circuit of claim 1, wherein the sensing circuit is a voltage divider implemented between the low rail and the high rail, and wherein the first voltage is the second output voltage.

4. The semiconductor circuit of claim 1, wherein the sensing circuit is a voltage divider implemented between the low rail and the high rail, wherein the first voltage is one of the voltage rails, wherein the at least one monitor FET comprises a body terminal, and wherein the second output voltage is received on the at least one monitor FET's the body terminal.

5. The semiconductor circuit of claim 1, wherein the feedback circuit comprises a differential amplifier, the differential amplifier is arranged to receive the first output voltage and a first reference voltage as inputs and to control a charge pump, wherein the charge pump generates the second output voltage.

6. The semiconductor circuit of claim 5, wherein the first reference voltage is derived from a bandgap reference circuit, and is essentially independent of temperature.

7. The semiconductor circuit of claim 1, wherein the semiconductor circuit is characterized as being a Static Random Access Memory (SRAM) circuit, and the large plurality of FET devices are characterized as being pass transistors in memory cells, wherein the pass transistors include gate electrodes, and the gate electrodes receive the second output voltage.

8. The semiconductor circuit of claim 1, wherein the semiconductor circuit is characterized as being a Static Random Access Memory (SRAM) circuit, and the large plurality of FET devices are characterized as being latching transistors in memory cells, wherein the latching transistors include body terminals, and the body terminals receive the second output voltage.

9. The semiconductor circuit of claim 8, wherein the latching transistors are NFET devices, and the value of the second output voltage is more negative than the low rail.

10. The semiconductor circuit of claim 8, wherein the latching transistors are PFET devices, and the value of the second output voltage is more positive than the high rail.

11. The semiconductor circuit of claim 1, wherein the semiconductor circuit is characterized as being a Dynamic Random Access Memory (DRAM) circuit, and the large plurality of FET devices are characterized as being access transistors in memory cells, wherein the access transistors include gate electrodes, and the gate electrodes receive the second output voltage.

12. The semiconductor circuit of claim 1, wherein the semiconductor circuit is characterized as being a Dynamic Random Access Memory (DRAM) circuit, and the large plurality of FET devices are characterized as being access transistors in memory cells, wherein the access transistors include body terminals, and the body terminals receive the second output voltage.

13. The semiconductor circuit of claim 1, wherein the semiconductor circuit is characterized as being a CMOS logic circuit, and the large plurality of FET devices are characterized as being logic transistors, wherein the logic transistors include body terminals, and the body terminals receive the second output voltage.

14. A method for reducing a temperature dependent leakage current in a semiconductor circuit, the method comprising:
converting the temperature dependent leakage current in at least one off-state monitor FET into a first output voltage;
comparing the first output voltage to a first reference voltage, wherein the first reference voltage is temperature independent, and wherein, based on the comparing, generating a second output voltage in proportion to the temperature dependent leakage current; and
receiving the second output voltage in a large plurality of FET devices in the semiconductor circuit, wherein the large plurality of FET devices have common properties with the at least one monitor FET, whereby the second output voltage is suitable to decrease the temperature dependent leakage current in the large plurality of FET devices.

15. The method of claim 14, wherein the semiconductor circuit comprises voltage rails, wherein the generating of the second output voltage comprises using a charge pump, wherein the second output voltage has a value outside of the voltage rails.

16. The method of claim 15, wherein the converting of the temperature dependent leakage current comprises implementing a voltage divider between one of the voltage rails and the second output voltage, wherein the voltage divider comprises the at least one monitor FET in an off-state.

17. The method of claim 14, wherein the method further comprises selecting the semiconductor circuit as a Static Random Access Memory (SRAM) circuit, selecting the large plurality of FET devices as pass transistors in memory cells, and applying the second output voltage on gate electrodes of the pass transistors.

18. The method of claim 14, wherein the method further comprises selecting the semiconductor circuit as a Static Random Access Memory (SRAM) circuit, selecting the large plurality of FET devices as latching transistors in memory cells, and applying the second output voltage on body terminals of the latching transistors.

19. The method of claim 14, wherein the method further comprises selecting the semiconductor circuit as a Dynamic Random Access Memory (DRAM) circuit, selecting the large plurality of FET devices as access transistors in memory cells, and applying the second output voltage on gate electrodes of the access transistors.

20. The method of claim 14, wherein the method further comprises selecting the semiconductor circuit as a Dynamic Random Access Memory (DRAM) circuit, selecting the large plurality of FET devices as access transistors in memory cells, and applying the second output voltage on body terminals of the access transistors.

21. The method of claim 14, wherein the method further comprises selecting the semiconductor circuit as a CMOS logic circuit, selecting the large plurality of FET devices as logic transistors, and applying the second output voltage on body terminals of the logic transistors.
